(19) United States
(12) Patent Application Publication
(10) Pub. No.: US 2026/0129907 A1
(43) Pub. Date: May 7, 2026

(54) CAPPED BACKSIDE CONTACTS

(71) Applicant: International Business Machines Corporation, Armonk, NY (US)

(72) Inventors: Fabio Carta, Pleasantville, NY (US); Ruilong Xie, Niskayuna, NY (US); Tao Li, Slingerlands, NY (US); Qianwen Chen, Fort Collins, CO (US); Joshua Mark Rubin, Albany, NY (US)

(21) Appl. No.: 18/934,387

(22) Filed: Nov. 1, 2024

(51) Int. Cl. H01L 29/417; H01L 29/06; H01L 29/423; H01L 29/66; H01L 29/775; H01L 29/786

(52) U.S. Cl. CPC H10D 30/6729; H10D 30/014; H10D 30/43; H10D 30/6735; H10D 30/6757; H10D 62/121; H10D 64/017

(57) ABSTRACT

A semiconductor integrated circuit device includes a backside contact in direct contact with a source/drain region and a backside contact cap in direct contact with the backside contact. The device further includes a backside spacer in direct contact with respective sidewalls of the backside contact and the backside contact cap. The device further includes a backside S/D region contact via in direct contact with the backside contact, in direct contact with the backside spacer, and in direct contact with the backside contact cap. The device may further include a backside gate region contact via. The backside contact cap may provide adequate electrical and structural protection of the backside contact which may enable a nearby placement of the backside gate region contact via. Consequently, wire/signal routing congestion issues may be reduced and functionality of an associated backside back end of line network may be enhanced.

### BACKGROUND

Some modern semiconductor integrated circuit (IC) devices utilize a direct backside contact (DBC) scheme. Typically, in this scheme, a backside contact placeholder is epitaxially grown prior to epitaxially growing a source/drain region thereupon. In order to more precisely control the epitaxial growth of the backside contact placeholders, typically, a respective backside contact placeholder is placed everywhere, or in each source/drain region canyon. Because there are some source/drain regions that do not utilize a backside contact, there are typically locations where the respective backside contact placeholders are retained.

### SUMMARY

In an embodiment of the disclosure, a semiconductor integrated circuit (IC) device is presented. The device includes a backside contact in direct contact with a source/drain region, a backside contact cap in direct contact with the backside contact, a backside spacer in direct contact with respective sidewalls of the backside contact and the backside contact cap, and a backside S/D region contact via in direct contact with the backside contact, in direct contact with the backside spacer, and in direct contact with the backside contact cap.

In another embodiment of the disclosure, another semiconductor IC device is presented. This device includes a plurality of channels each directly connected to a first source/drain (S/D) region and directly connected to a second S/D region, a first backside contact in direct contact with the first S/D region, and a second backside contact in direct contact with the second S/D region. This device further includes a first backside contact cap in direct contact with the first backside contact, a second backside contact cap in direct contact with the second backside contact, a first backside spacers in direct contact with respective sidewalls of the first backside contact and the first backside contact cap, and a second backside spacers in direct contact with respective sidewalls of the second backside contact and the second backside contact cap. This device further includes a backside gate contact via in direct contact with a gate, in direct contact with one of the first backside spacers, and in direct contact with one of the second backside spacers.

In yet another embodiment of the disclosure, another semiconductor IC device is presented. This device includes a first source/drain (S/D) region, a second S/D region, a first backside contact in direct contact with a backside of the first S/D region, a second backside contact in direct contact with a backside of the second S/D region, a first backside contact cap in direct contact with the first backside contact, a second backside contact cap in direct contact with the second backside contact, and a backside S/D contact via in direct contact with the first backside contact and in direct contact with the first backside contact cap.

The above summary is not intended to describe each illustrated embodiment or every implementation or example of the present disclosure.

### BRIEF DESCRIPTION OF THE DRAWINGS

The drawings included in the disclosure are incorporated into, and form part of, the specification. They illustrate embodiments of the present disclosure and, along with the description, explain the principles of the disclosure. The drawings are only illustrative of certain embodiments and do not limit the disclosure.

FIG. 1A through FIG. 1C depict a cross-section view of illustrative semiconductor IC devices that includes capped backside contacts, according to one or more embodiments of the disclosure.

FIG. 2 depicts a partial structure top-down view of an illustrative semiconductor IC device, according to one or more embodiments of the disclosure.

FIG. 3 through FIG. 20 depict various fabrication structure cross-section views of an illustrative semiconductor IC device that is formed to include capped backside contacts, according to one or more embodiments of the disclosure.

FIG. 21 depicts a method of fabricating a semiconductor IC device that includes capped backside contacts, according to one or more embodiments of the disclosure.

### DETAILED DESCRIPTION

The embodiments of the present disclosure relate to fabrication methods and resulting structures for semiconductor IC devices. More specifically, the present disclosure relates to fabrication methods and resulting semiconductor integrated circuit (IC) devices that include capped backside contacts. This scheme may be utilized to form semiconductor IC devices without the traditional backside contact placeholders. A portion of the cap may be removed which may expose a corresponding portion of the backside contact. A backside contact via may be formed in direct connection with the exposed portion of the backside contact. Further, a cap associated with a backside contact may be adequately maintained and may adequately electrically isolate a backside gate contact via from the backside contact.

A transistor is a type of microdevice that may be fabricated in semiconductor IC device front-end-of-line (FEOL) fabrication operations. Conventional transistors, or the like, incorporate planar field effect transistors (FETs) in which current flows through a semiconducting channel between a source and a drain, in response to a voltage applied to the gate. The semiconductor industry strives to obey Moore's law, which holds that each successive generation of integrated circuit devices shrinks to half its size and operates twice as fast. As device dimensions have shrunk, however, conventional silicon device geometries and materials have had trouble maintaining switching speeds without incurring failures such as, for example, leaking current from the device into the semiconductor substrate. Several new technologies emerged that allowed chip designers to continue shrinking transistor sizes. A FET generally is a transistor in which output current, i.e., source-drain current, is controlled by a voltage applied to an associated gate. A FET typically has three terminals, i.e., a gate structure, a source region, and a drain region. A gate structure is a structure used to control output current (i.e., flow of carriers in the channel) of a semiconducting device through electrical or magnetic fields. A channel is the region of the FET underlying the gate structure and between the source and drain of the semiconductor IC device that becomes conductive when the semiconductor device is turned on. The source is a doped region in the semiconductor IC device, in which majority carriers are flowing into the channel. A drain is a doped region in the semiconductor IC device located at the end of the channel, in which carriers are flowing out of the transistor through the drain.

One technology change modified the structure of the FET from a planar device to a three-dimensional device in which the semiconducting channel was replaced by a fin that extends out from the plane of the substrate. In such a device, commonly referred to as a FinFET, the control gate wraps around three sides of the fin to influence current flow from three surfaces instead of one. The improved control achieved with a 3D design results in faster switching performance and reduced current leakage. Building taller devices has also permitted increasing the device density within the same footprint that had previously been occupied by a planar FET.

The FinFET concept was further extended by developing a gate all-around FET, or GAA FET, in which the gate fully wraps around one or more channels for maximum control of the current flow therein. In the GAA FET, the channels can take the form of nanolayers, nanolayers, or the like, that are isolated from the substrate. In the GAA FET, channel surfaces are in respective contact with the source and drain and other respective channel surfaces are in contact with and surrounded by the gate.

The flowcharts and cross-sectional diagrams in the drawings illustrate a method of fabricating a semiconductor IC device, such as a processor, filed programmable gate array (FPGA), memory module, or the like. In some alternative implementations, the fabrication steps may occur in a different order than that which is noted in the drawings, and certain additional fabrication steps may be implemented between the steps noted in the drawings. Moreover, any of the layered structures depicted in the drawings may contain multiple sublayers.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” if the relevant characteristics and functionalities of layer “A”and layer “B”are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the depicted structure(s) as oriented. The terms “overlying,” “atop,” “on top,” “above”, “below”, “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

The terms “about,” “substantially,” “approximately,” and variations thereof, are intended to include the degree of error associated with measurement of the particular quantity based upon the equipment available at the time of filing the application. For example, substantial coplanarity between various materials can include an appropriate manufacturing tolerance of ±8%, ±5%, ±2%, or the like, difference between the coplanar materials.

As used herein, the term “coplanar” refers to two surfaces that lie in a common plane. In other words, two surfaces are coplanar if there exists a geometric plane that contains all the points of both of the surfaces. Accordingly, two surfaces may be referred to as substantially coplanar despite deviations from coplanarity, so long as those deviations do not impact the desired result of the coplanarity.

As used herein, the terms “selective” or “selectively” in reference to a material removal or etch process denote that the rate of material removal for a first material is greater than the rate of removal for at least another material of the structure to which the material removal process is applied. For example, in certain embodiments, a selective etch may include an etch chemistry that removes a first material selectively to a second material by a ratio of 2:1 or greater, e.g., 5:1, 10:1 or 20:1.

For the sake of brevity, conventional techniques related to semiconductor IC device fabrication may or may not be described in detail and/or depicted herein. Moreover, the various tasks and process steps described herein can be incorporated into a more comprehensive procedure or process having additional steps or functionality not described and/or not depicted in detail herein. Various steps in the manufacture of semiconductor devices are well known and so, in the interest of brevity, many conventional steps will only be mentioned briefly herein, will be omitted entirely without providing the well-known process details, and/or will not be depicted.

In general, the various processes used to form a semiconductor IC device that may be packaged into an IC package fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Turning now to an overview of technologies that are more specifically relevant to aspects of the present disclosure, a metal-oxide-semiconductor field-effect transistor (MOSFET) may be used for amplifying or switching electronic signals. The MOSFET has a source electrode, a drain electrode, and a metal oxide gate electrode. The metal gate portion of the metal oxide gate electrode is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (nFET) and p-type field effect transistors (pFET) are two types of complementary MOSFETs. The nFET includes n-doped source and drain regions and uses electrons as the charge carrier. The pFET includes p-doped source and drain regions and uses holes as the charge carrier. Complementary metal oxide semiconductor (CMOS) is a technology that uses complementary and symmetrical pairs of p-type and n-type MOSFETs to implement logic functions. As mentioned above, hole mobility on the pFET may have an impact on overall device performance.

The wafer footprint of a FET is related to the electrical conductivity of the channel material. If the channel material has a relatively high conductivity, the FET can be made with a correspondingly smaller wafer footprint. A method of increasing channel conductivity and decreasing FET size is to form the channel as a nanostructure, such as a nano wire, nano ribbon, nanolayer, nanolayer, or the like, hereinafter referred to as a nanolayer. For example, a GAA FET provides a relatively small FET footprint by forming the channel region as a series of vertically stacked nanolayers. In a GAA configuration, a GAA FET includes a source region, a drain region and vertically stacked nanolayer channels between the source and drain regions. These devices typically include one or more suspended nanolayers that serve as the channel. A gate surrounds the stacked nanolayers and regulates electron flow through the nanolayers between the source and drain regions. GAA FETs may be fabricated by forming alternating layers of active nanolayers and sacrificial nanolayers. The sacrificial nanolayers are released from the active nanolayers before the FET device is finalized. For n-type FETs, the active nanolayers are typically silicon (Si) and the sacrificial nanolayers are typically silicon germanium (SiGe). For p-type FETs, the active nanolayers can be SiGe and the sacrificial nanolayers can be Si. In some implementations, the active nanolayers of a p-type FET can be SiGe or Si, and the sacrificial nanolayers can be Si or SiGe. Forming the nanolayers from alternating layers of active nanolayers formed from a first type of semiconductor material (e.g., Si for n-type FETs, and SiGe for p-type FETs) and sacrificial nanolayers formed from a second type of semiconductor material (e.g., SiGe for n-type FETs, and Si for p-type FETs) may provide for improved channel electrostatics control.

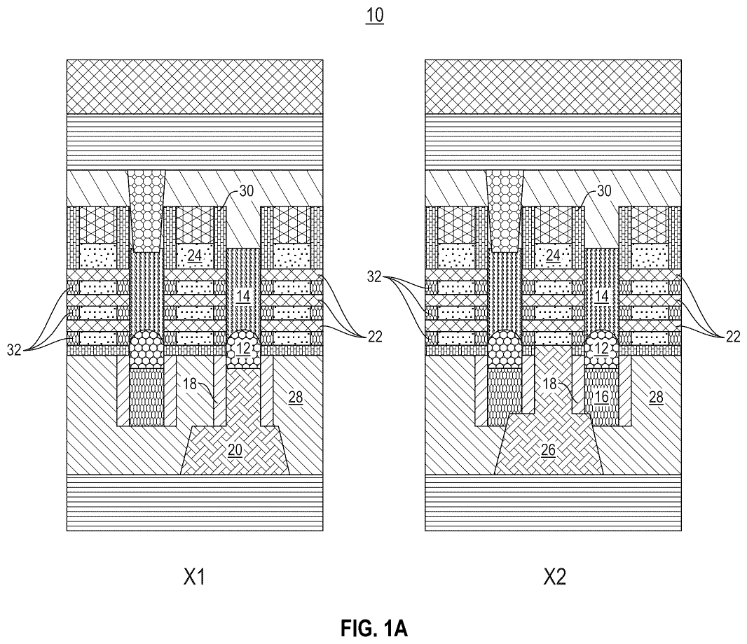

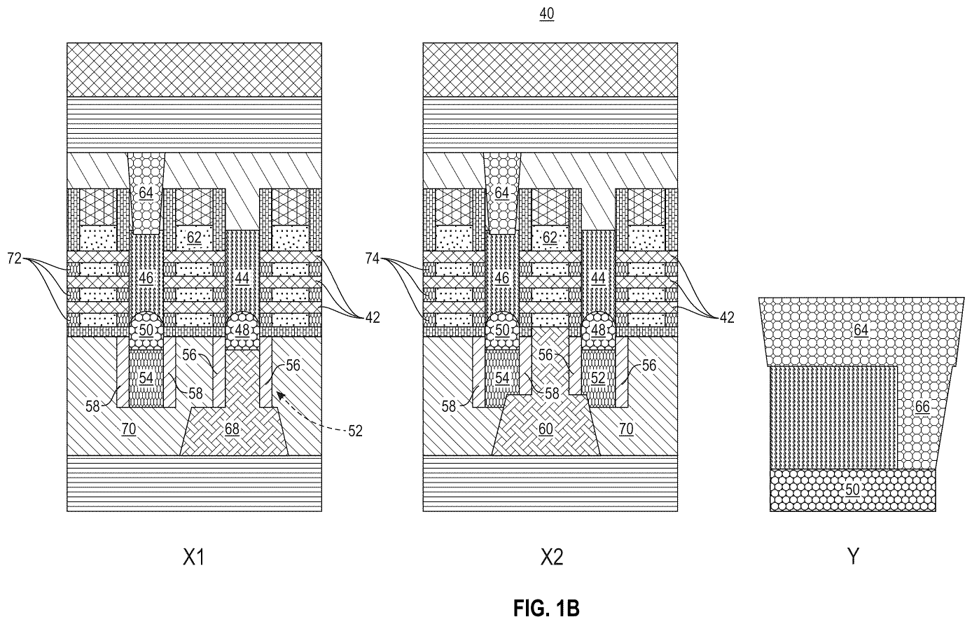

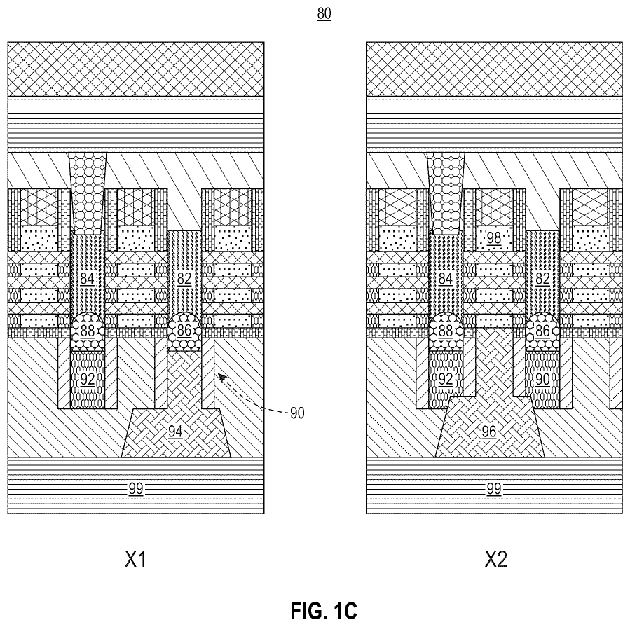

Referring now to the figures, FIG. 1A depicts cross-sectional views of an illustrative semiconductor integrated circuit (IC) device 10. The semiconductor IC device 10 includes a backside contact 12 in direct contact with a source/drain (S/D) region 14. The semiconductor IC device 10 further includes a backside contact cap 16 in direct contact with the backside contact 12 and a backside spacer 18 in direct contact with respective sidewalls of the backside contact 12 and the backside contact cap 16. The semiconductor IC device 10 further includes a backside S/D region contact via 20 in direct contact with the backside contact 12, in direct contact with the backside spacer 18, and in direct contact with the backside contact cap 16 (e.g., in a different X cross-section plane than those depicted).

In an example, the semiconductor IC device 10 further includes a plurality of channels 22 directly connected to the S/D region 14, a gate 24 directly connected to the plurality of channels 22, and a backside gate contact via 26 in direct contact with the gate 24, in direct contact with the backside spacer 18, and in direct contact with the backside contact cap 16.

In an example, the semiconductor IC device 10 further includes a backside interlayer dielectric (ILD) 28 in direct contact with the backside spacer 18, in direct contact with the backside S/D region contact via 20, and in direct contact with the backside gate contact via 26.

In an example, the backside contact cap 16 is composed of a first dielectric material, the backside spacer 18 is composed of a second dielectric material, and the backside ILD 28 is composed of a third dielectric material. Each of the first dielectric material, the second dielectric material, and the third dielectric material are relatively different dielectric materials. For example, the relatively different materials may provide etch selectivity so as to form the backside S/D region contact via 20 and/or the backside gate contact via 26.

In an example, the semiconductor IC device 10 further includes a gate spacer 30 in direct contact with the gate 24 and a plurality of inner spacers 32, each inner spacer of the plurality of inner spacers 32 in direct contact with at least one channel of the plurality of channels 22.

In an example, the gate spacer 30, the plurality of inner spacers 32, and the backside spacer 18 are vertically inline. In an example, a topmost surface of the backside contact 12 is below a bottommost channel of the plurality of channels 22 and a top surface of the backside spacer 18.

FIG. 1B depicts cross-sectional views of another illustrative semiconductor integrated circuit (IC) device 40. The semiconductor IC device 40 includes a plurality of channels 42 each directly connected to a first source/drain (S/D) region 44 and directly connected to a second S/D region 46. The semiconductor IC device 40 includes a first backside contact 48 in direct contact with the first S/D region 44 and a second backside contact 50 in direct contact with the second S/D region 46. The semiconductor IC device 40 includes a first backside contact cap 52 in direct contact with the first backside contact 48 and a second backside contact cap 54 in direct contact with the second backside contact 50. The semiconductor IC device 40 includes first backside spacers 56 in direct contact with respective sidewalls of the first backside contact 48 and the first backside contact cap 52. The semiconductor IC device 40 includes second backside spacers 58 in direct contact with respective sidewalls of the second backside contact 50 and the second backside contact cap 54. The semiconductor IC device 40 includes a backside gate contact via 60 in direct contact with a gate 62, in direct contact with one of the first backside spacers 56, and in direct contact with one of the second backside spacers 58.

In an example, the backside gate contact via 60 is in direct contact with the first backside contact cap 52 and in direct contact with the second backside contact cap 54. In an example, the semiconductor IC device 40 includes a frontside contact 64 directly connected to a top surface of the second S/D region 46. In an example, the semiconductor IC device 40 further includes a frontside contact via 66 directly connected to the frontside contact 64, directly connected to the second backside contact 50, and directly connected to a sidewall of the second S/D region 46. In this manner, a wraparound frontside contact may be formed in which the wraparound contact is in direct contact with three of more sides of the S/D region.

In an example, the semiconductor IC device 40 further includes a backside S/D contact via 68 in direct contact with the first backside contact 48 and in direct contact with the first backside spacers 56. In an example, the semiconductor IC device 40 further includes a backside interlayer dielectric (ILD) 70 in direct contact with the first backside spacers 56, in direct contact with the second backside spacers 58, in direct contact with the backside S/D region contact via 68, and in direct contact with the backside gate contact via 60.

In an example, the semiconductor IC device 40 further includes a first plurality of inner spacers 72. Each inner spacer of the first plurality of inner spacers 72 is in direct contact with at least one channel of the plurality of channels 42 and in direct contact with the first S/D region 44. In this example, the semiconductor IC device 40 further includes a second plurality of inner spacers 74, each inner spacer of the second plurality of inner spacers 72 is in direct contact with at least one channel of the plurality of channels 42 and in direct contact with the second S/D region 46. In an example, the first plurality of inner spacers 72 and one of the first backside spacers 56 are vertically inline and wherein the second plurality of inner spacers 74 and one of the second backside spacers 58 are vertically inline.

In an example, a respective topmost surface of the first backside contact 48 and the second backside contact 50 are both below a bottommost channel of the plurality of channels 42. In an example, respective sidewalls of the first backside contact 48 and respective sidewalls of the backside S/D contact via 68 are directly connected to a respective one of the first backside spacers 56. In an example, the backside gate contact via 60 is in direct contact with a sidewall of one of the first backside spacers 56 and in direct contact with a sidewall of one of the second backside spacers 58.

FIG. 1C depicts cross-sectional views of another illustrative semiconductor integrated circuit (IC) device 80. The semiconductor IC device 80 includes a first source/drain (S/D) region 82, a second S/D region 84, a first backside contact 86 in direct contact with a backside of the first S/D region 82 and a second backside contact 88 in direct contact with a backside of the second S/D region 84. The semiconductor IC device 80 further includes a first backside contact cap 90 in direct contact with the first backside contact 86, a second backside contact cap 92 in direct contact with the second backside contact 88, and a backside S/D contact via 94 in direct contact with the first backside contact 86 and in direct contact with the first backside contact cap 90 (e.g., in a different X cross-section plane than those depicted).

In an example, the semiconductor IC device 80 further includes a backside gate contact via 96 in direct contact with a gate 98, in direct contact with the first backside contact cap 90, and in direct contact with second backside contact cap 92, and a backside back end of line (BEOL) network 99 connected to the backside S/D contact via 94 and connected to the backside gate contact via 96.

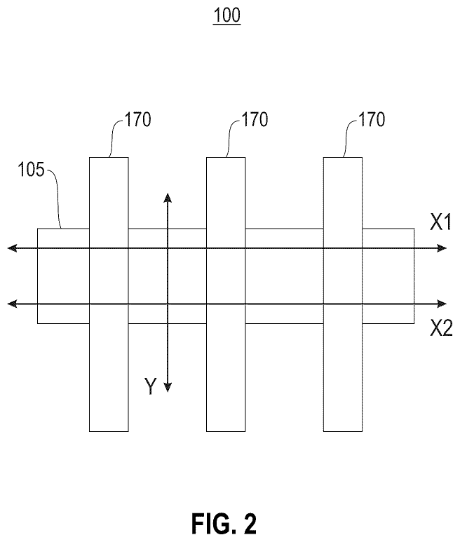

FIG. 2 depicts a partial structure top-down view of an illustrative semiconductor IC device 100, according to one or more embodiments of the disclosure. As currently depicted, semiconductor IC device 100 includes a nanolayer row 105 and replacement gate structures 170. FIG. 2 also depicts cross-sectional planes of the various cross-sectional views of at least some of the drawings. The X1 cross-sectional plane and the X2 cross-sectional plane are both through a nanolayer row 105 and across replacement gate structures 170, but at respective different sides of the nanolayer row 105. The Y cross-sectional plane is parallel to and between adjacent replacement gate structures 170 and across nanolayer row 105.

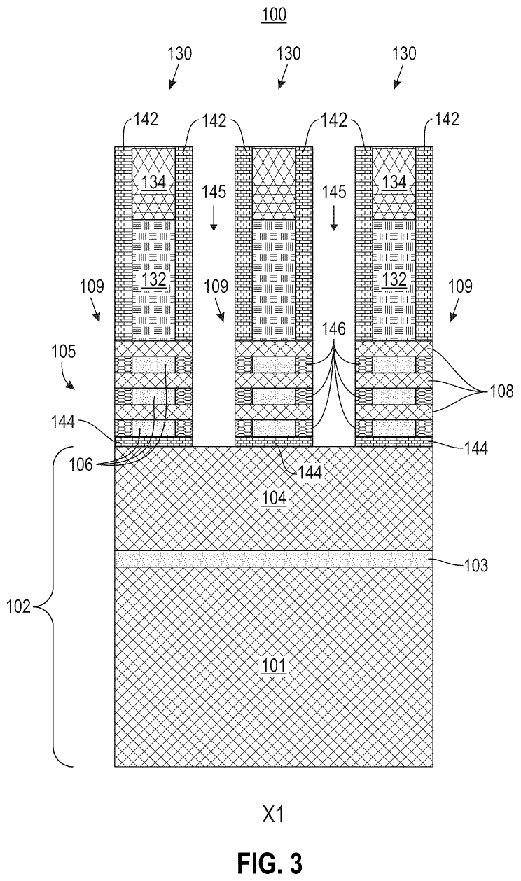

FIG. 3 depicts a cross-sectional initial fabrication view of the semiconductor IC device 100. At this initial fabrication stage, the semiconductor IC device 100 may include a substrate structure 102, shallow trench isolation (STI) regions (not shown), a nanolayer row 105 that has been separated into nanolayer stacks 109 with alternating active nanolayers 108 and sacrificial nanolayers 106, sacrificial gate structures 130, gate spacers 142, and bottom isolation regions 144.

For clarity, the fabrication of the semiconductor IC device 100 at the present stage may utilize processes that may now be known or that may be developed in the future. For illustration purposes, a particular fabrication process to form semiconductor IC device 100 at the present stage is presented below. This illustrative methodology may be one of many that may achieve or result in the initial semiconductor IC device 100, as depicted. When components referenced in the illustrative methodology below are depicted in FIG. 3, such associated component numeral is expressly utilized. Otherwise, when components are referenced in the illustrative methodology that are not depicted in FIG. 3, a component numeral is not denoted.

The illustrative semiconductor IC device 100 may be formed by initially providing or forming a substrate structure 102. The substrate structure 102 may be a bulk-semiconductor substrate. In one example, the bulk-semiconductor substrate may be a silicon-containing material. In another implementation, the substrate structure 102 includes an upper substrate 104, a lower substrate 101, and an etch stop layer 103 between the upper substrate and the lower substrate. The upper substrate 104 and the lower substrate 101 may be comprised of any suitable semiconductor material(s), and the etch stop layer 103 may be a dielectric material with etch selectivity to one or both upper substrate 104 and/or the lower substrate 101.

The illustrative semiconductor IC device 100 may be formed by forming nanolayers over the substrate structure by forming a bottommost sacrificial nanolayer and then a series of alternating sacrificial nanolayers 106 and active nanolayers 108. In certain examples, the bottommost sacrificial nanolayer is initially formed directly on an upper surface of the substrate structure 102.

The nanolayers may be formed by fabricating the alternating series of sacrificial nanolayers, such as SiGe sacrificial nanolayers, and active nanolayers, such as Si nanolayers. The sacrificial nanolayers 106 can have Ge percentages ranging from 20% to 45% and the bottommost sacrificial layer may have higher Ge percentage so as to provide etch selectivity relative to the sacrificial nanolayers 106. In an implementation, the alternating active sacrificial nanolayer 106 and active nanolayer 108 may be formed by epitaxially growing each layer until the desired number and desired thicknesses of the layers are achieved. Any number of alternating nanolayers can be provided. Epitaxial materials can be grown from gaseous or liquid precursors. For example, epitaxial materials can be grown using vapor-phase epitaxy (VPE), molecular-beam epitaxy (MBE), liquid-phase epitaxy (LPE), or other suitable processes.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases are controlled and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed. For example, an epitaxially grown semiconductor material deposited on a (100) orientated crystalline surface will take on a (100) orientation. In some embodiments, epitaxial growth and/or deposition processes are selective to forming on semiconductor surfaces, and generally do not deposit material on exposed surfaces, such as silicon dioxide or silicon nitride surfaces.

Although it is specifically contemplated that the sacrificial nanolayers can be formed from SiGe and that the active nanolayers can be formed from Si, it should be understood that any appropriate materials can be used instead, as long as the semiconductor materials have etch selectivity with respect to one or more of the others, as is consistent with the description of the fabrication stages herein. Although it is specifically contemplated that the sacrificial nanolayers 106 and the active nanolayers 108 are formed by epitaxial growth, such nanolayers can be formed by any appropriate deposition mechanism.

Further, in the depicted fabrication stages, the nanolayers may be patterned into nanolayer rows 105, and STI regions may be formed within the substrate structure 102 adjacent to the nanolayer rows 105.

The one or more nanolayer rows 105 may be formed by lithography and etching techniques. Following the nanolayer row 105 patterning process, the one or more nanolayer rows 105 are formed. The removal of undesired portion(s) of the nanolayers may further remove undesired portions of substrate structure 102 that are adjacent to respective footprints of nanolayer rows 105 to form STI region openings. A STI region may be formed upon and/or within the substrate structure 102 within respective STI region openings. The STI regions may be formed by depositing electrical dielectric material(s) within respective STI region opening(s). A top surface of the one or more STI regions may be initially coplanar with or below a top surface of the substrate structure 102.

Sacrificial gate structures 130 may be formed and may include a sacrificial gate liner (not shown), a sacrificial gate 132, and a sacrificial gate cap 134. The sacrificial gate structures 130 may be formed by initially depositing a sacrificial gate liner (e.g., a dielectric, oxide, or the like) upon the one or more STI regions and upon and around the one or more nanolayer rows 105. The sacrificial gate structures 130 may further be formed by subsequently depositing a sacrificial gate layer (e.g., amorphous silicon, or the like) upon the sacrificial gate liner layer. The thickness of the sacrificial gate layer may be such that the top surface of the sacrificial gate layer is above the top surface of the one or more nanolayer rows 105. The sacrificial gate structures 130 may further be formed by forming a gate cap layer upon the sacrificial gate layer. The gate cap layer may be formed by depositing a mask material, such as a hard mask material, such as a silicon oxide, or the like, upon the sacrificial gate layer. The gate cap layer may be composed of one or more layers of masking materials to protect the sacrificial gate layer and/or other underlying materials during subsequent processing of semiconductor IC device 100.

The one or more sacrificial gate structures 130 may further be formed by patterning the gate cap layer, sacrificial gate layer, and sacrificial gate liner by, for example, using lithography and etch processes to remove undesired portions and retain desired portion(s), respectively. The retained desired portion(s) of the gate cap layer, sacrificial gate layer, and sacrificial gate liner may form the sacrificial gate liner (not shown), the sacrificial gate 132, and the sacrificial gate cap 134, respectively, of each of the one or more sacrificial gate structures 130.

The semiconductor IC device 100 may be further formed by removing the bottommost sacrificial layer from the nanolayer rows 105, with forming gate spacers 142, and with forming bottom isolation regions 144. The bottommost sacrificial layer may be removed from the nanolayer rows by a etch selective to the respective materials of the active nanolayers 108, the sacrificial nanolayers 106, and the sacrificial gate structures. For clarity, though the bottommost sacrificial layer, the other nanolayers in the nanolayer rows 105 may be structurally supported by the sacrificial gate structures 130 that wrap therearound.

The gate spacer(s) 142 and the bottom isolation region 144 may be formed by a conformal deposition of a dielectric material, such as silicon nitride, SiBCN, SiNC, SiN, SiCO, SiNOC, or a combination thereof, or the like, upon STI regions, upon around the one or more sacrificial gate structures 130, and upon, below, and around the one or more nanolayer rows 105. Subsequently, undesired portions of dielectric material may be removed while desired portions the dielectric material may be retained to thereby forming the gate spacer(s) 142 located generally upon the sidewalls of the sacrificial gate structures 130 and the bottom isolation region 144 underneath the nanolayer rows 105.

The semiconductor IC device 100 may be further fabricated by forming source/drain canyons 145 and may separate the nanolayer rows into nanolayers stacks 109. The source/drain canyons 145 may be formed within the nanolayer rows 105 and within the substrate structure 102 between gate spacers 142 of neighboring sacrificial gate structures 130. In other words, a single nanolayer row 105 may be separated, by one or more recesses, into multiple nanolayer stacks each located underneath at a portion of respective sacrificial gate structure 130 and associated gate spacers 142.

The source/drain canyons 145 may be formed between adjacent sacrificial gate structures 130 by removing respective portions of the sacrificial nanolayers 106 and active nanolayers 108 that are between gate spacers 142 of adjacent or neighboring sacrificial gate structures 130 and may expose the bottom isolation region 144 there below. As the gate spacers 142 and the sacrificial gate structures 130 may be utilized to protect the underlying portions of sacrificial nanolayers 106, active nanolayers 108, respective sidewalls of the nanolayer stacks may be substantially coplanar and substantially vertical with the outer sidewalls of the gate spacers 142 there above.

The semiconductor IC device 100 may be further fabricated by opening the bottom isolation region 144 and exposing the substrate structure 102 within the S/D canyons 145. The bottom isolation region 144 may therefore be separated and may be retained underneath each nanolayer stack 109.

As used herein, “substantially vertical” sidewalls deviate from a direction normal to a major surface (e.g., top surface, etc.) of the substrate structure 102 by less than 5°, e.g., 0°, 1°, 2°, 3°, 4°, or 5°, including ranges between any of the foregoing values.

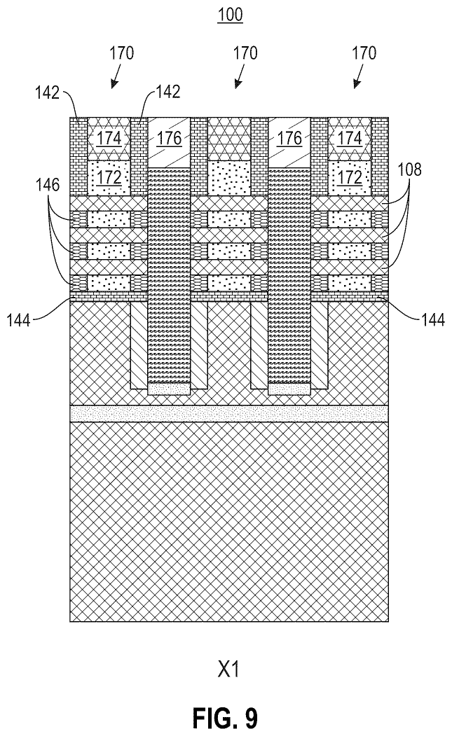

The illustrated semiconductor IC device 100 may be further fabricated by forming horizontal or lateral indents (shown with a respective inner spacer 146 formed therewithin) by laterally or horizontally removing respective portions of sacrificial nanolayers 106 within the nanolayer stacks. The indents may be formed by a reactive ion etch (RIE) process, which can remove portions of the sacrificial nanolayers. The horizontal depth of the indents may be chosen to set a length for a replacement gate structure 170, shown in FIG. 9, that is formed in place of one sacrificial gate structure 130. When the sacrificial nanolayers 106 are composed of SiGe and when active nanolayers 108 are Si, the directional RIE can use a boron-based chemistry or a chlorine-based chemistry, for example, which recesses or removes the exposed end portions of sacrificial nanolayers 106 (e.g., end portions of sacrificial nanolayers generally below gate spacer 142) selective to the Si active nanolayers 108. In alternative implementations when sacrificial nanolayers 106 are not SiGe and when active nanolayers 108 are not Si, the directional etch of the sacrificial nanolayers 106 may generally be selective to the active nanolayers 108, gate spacers 142, STI regions, and/or substrate structure 102.

The illustrated semiconductor IC device 100 may be further fabricated by forming a respective inner spacer 146 within each indent. The one or more inner spacers 146 can be formed by ALD or CVD or any other suitable deposition technique that deposits a dielectric material within the indent(s), thereby forming the inner spacer(s) 146. In some examples, the inner spacer(s) 146 are composed of a low-κ dielectric material (a material with a lower dielectric constant relative to SiO₂), SiN, SiO, SiBCN, SiOCN, SiCO, etc. or any other suitable dielectric material. In certain implementations, after the formation of the inner spacer(s) 146, a directional etch process is performed to create substantially vertical sidewalls of the inner spacer(s) 146 that are coplanar with the substantially vertical sidewalls of the active nanolayers 108, of the gate spacers 142, or the like.

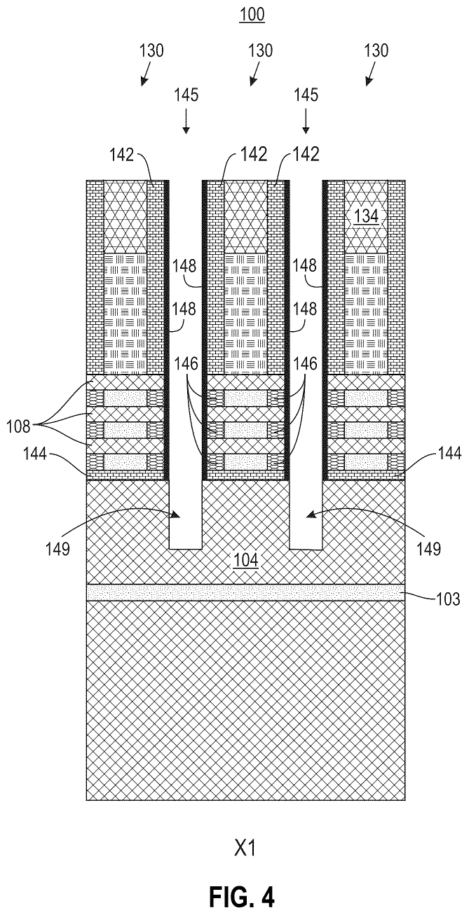

FIG. 4 depicts cross-sectional views of the semiconductor IC device 100 after fabrication operations, in accordance with embodiments of the present disclosure. In the depicted fabrication stages, channel edge liners 148 are formed and S/D canyons 145 are deepened by forming substrate recesses 149.

The channel edge liners 148 may be formed by a conformal deposition of a dielectric material, such as silicon oxide, that has etch selectivity to the material of gate spacers 142, inner spacers 146, active nanolayers 108, etc. The material of the channel edge liners may be the same material or the same material type as the gate caps 134. The dielectric may be deposited as a blanket layer upon the sacrificial gate cap 134, gate spacers 142, active nanolayers 108, inner spacers 146, STI regions, and substrate structure 102. Subsequently, undesired horizontal portions of dielectric material may be removed while desired vertical portions the dielectric material may be retained to thereby form the channel edge liners 148 located generally upon the sidewalls of at least the gate spacers 142, active nanolayers 108, inners spacers 146, bottom isolation region 144, or the like.

The substrate recesses 149 may be formed by deepening the source/drain canyons 145 within the substrate structure 102 between neighboring sacrificial gate structures 130. The substrate structure 102 may be removed by an directional etch process that removes the material of the upper substrate 104 in line with the S/D canyons 145 and that may be controlled so that the well surface of the source/drain canyons 145 stops above the etch stop layer 103 of the substrate structure 102. This etch may be selective to the respective materials of the gate caps 134, the gate spacers 142, the STI regions, and the channel edge liners 148, or the like.

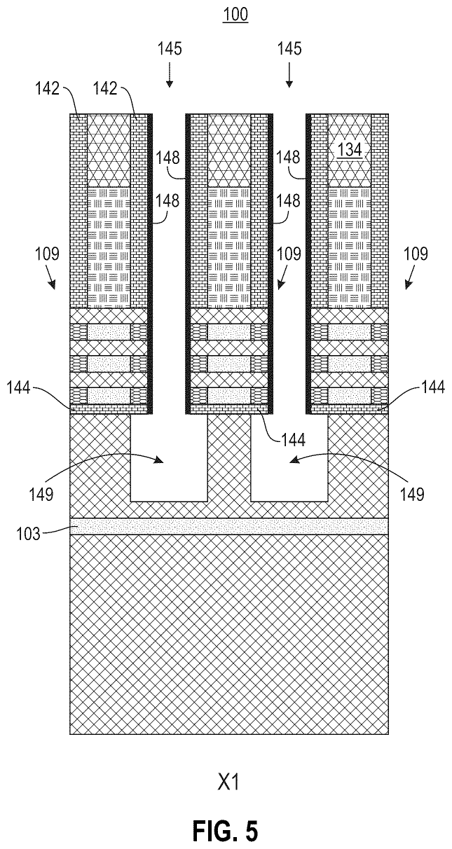

FIG. 5 depicts cross-sectional views of the semiconductor IC device 100 after fabrication operations, in accordance with embodiments of the present disclosure. In the depicted fabrication stages, substrate recesses 149 may be downwardly and laterally expanded.

The expanded substrate recesses 149 may be formed by a multidirectional etch that removes the material of the upper substrate 104 and that may be controlled so that the well surface of the expanded substrate recesses 149 stops above the etch stop layer 103 of the substrate structure 102. This etch may be selective to the respective materials of the gate caps 134, the gate spacers 142, the STI regions, and the channel edge liners 148, or the like. For clarity, though depicted as polygonal shaped, the expanded substrate recesses 149 may be curved, bowl shaped, or the like. The expanded substrate recesses 149 may expose the bottom isolation region 144 and may generally undercut the nanolayer stacks 109 there above.

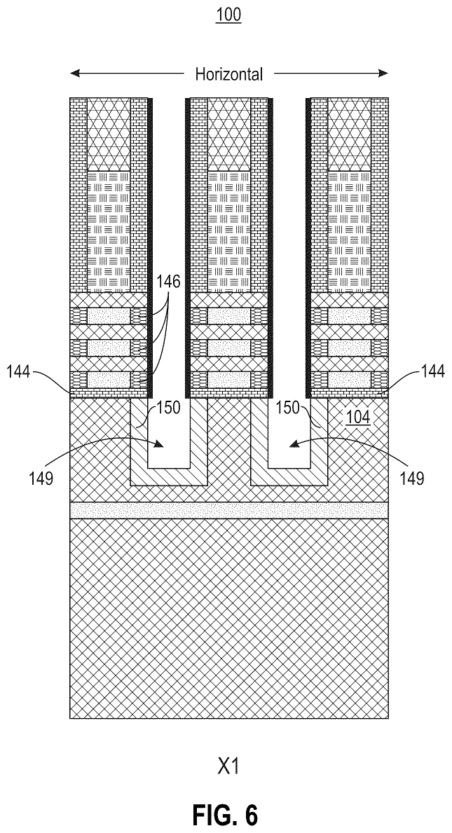

FIG. 6 depicts cross-sectional views of the semiconductor IC device 100 after fabrication operations, in accordance with embodiments of the present disclosure. In the depicted fabrication stages, a backside contact spacer 150 layer may be formed within respective expanded substrate recesses 149.

The backside contact spacer 150 layer may be formed by a selective deposition of a dielectric, such as a silicon nitride, that forms on surfaces that are not composed of the material of at least the channel edge liners 148. For example, the backside contact spacer 150 layer may be selectively formed upon the upper substrate 104 within the expanded substrate recesses 149. Due to the selective deposition, the backside contact spacer 150 layer may not be formed upon at least the channel edge liners 148. The thickness of the backside contact spacer 150 layer may be substantially the same as a horizontal thickness of the inner spacers 146.

Subsequently, undesired horizontal portions of backside contact spacer 150 layer may be removed from the substantially bottom or well surface of the expanded substrate recesses 149, thereby exposing a portion of the upper substrate 104 within the expanded substrate recesses 149. The desired vertical portions the backside contact spacer 150 layer may be retained and may thereby form backside contact spacer(s) 150 located generally upon the sidewalls of the expanded substrate recesses 149.

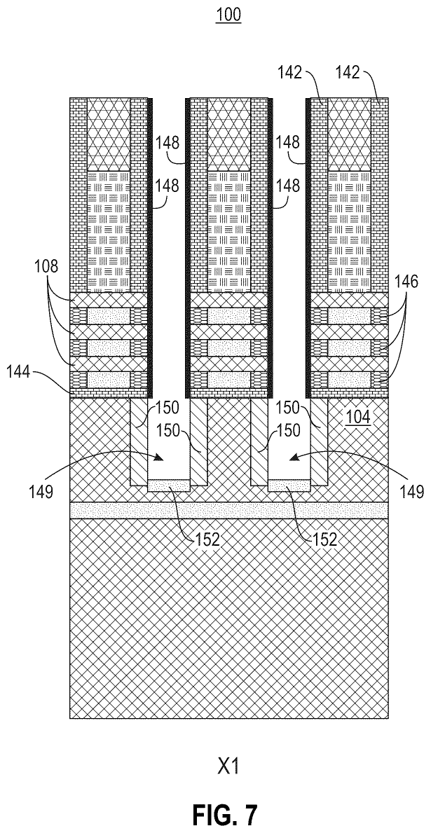

FIG. 7 depicts cross-sectional views of the semiconductor IC device 100 after fabrication operations, in accordance with embodiments of the present disclosure. In the depicted fabrication stages, an etch stop layer 152 may be formed within respective substrate recesses 149 inside of the backside contact spacer(s) 150.

The etch stop layer 152 may be formed by epitaxially growing an epitaxial material from exposed substrate structure 102 surface(s) within the substrate recesses 149. For example, etch stop layer 152 may be epitaxially grown from the well surface of the substrate recesses 149 that is exposed by the backside contact spacer(s) 150 formation stage. The etch stop layer 152 may consist of a material that has etch selectively relative to the material of the upper substrate 104. For example, when the material of the upper substrate is Si, the material of the etch stop layer 152 may be SiGe. Subsequently, the channel edge liners 148 may be removed by a substrative removal process, such as a etch that removes the channel edge liners 148 selective to the respective materials of the etch stop layer 152, backside contact spacer(s) 150, bottom isolation region 144, inner spacers 146, gate spacers 142, or the like.

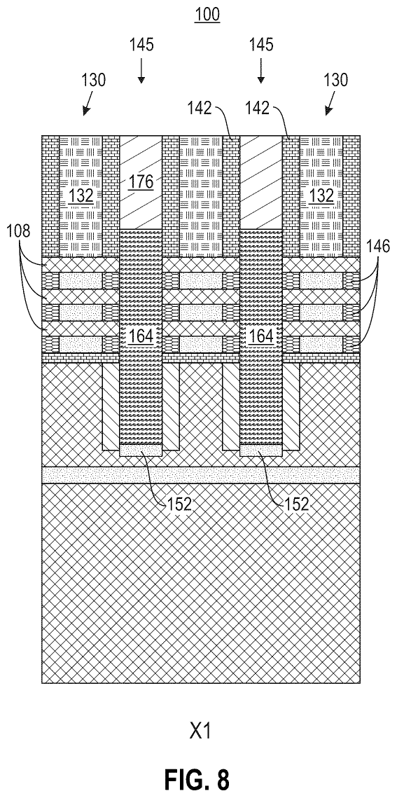

FIG. 8 depicts cross-sectional views of the semiconductor IC device 100 after fabrication operations, in accordance with embodiments of the present disclosure. In the depicted fabrication stages, a respective source/drain (S/D) region 164 may formed upon each etch stop layer 152 within S/D canyon 145 and an interlayer dielectric 176 may be formed upon the S/D region 164 within the S/D canyon 145.

The respective S/D regions 164 may be formed upon a particular etch stop layer 152. The S/D regions 164 may be formed in a sequential process so that, for example, p-doped S/D regions 164 may be formed in a first formation sequence and then n-doped S/D regions 164 may be formed in a second formation sequence, or vice versa.

Each S/D region 164 may form either a source or a drain, respectively, of a respective transistor and is connected to respective end surfaces of the active nanolayers 108 of one or more nanolayer stacks. Each S/D region 164 may be composed of a semiconductor material and a dopant. As used herein, a “source/drain” region can be a source region or a drain region depending on subsequent wiring and application of voltages during operation of the applicable transistor.

The semiconductor material that provides each of the S/D regions 164 may be composed of one of the semiconductor materials mentioned above for the semiconductor structure 102. For example, the semiconductor material that provides the S/D region 164 can be compositionally the same as each active nanolayer 108, can be compositionally the same as etch stop layer 152. For example, one or more S/D regions 164 may be composed of Si and one or more other S/D regions 164 may be composed of SiGe. The dopant that is present in the S/D regions 164 can be either a p-type dopant or an n-type dopant. The term “p-type” refers to the addition of impurities to an intrinsic semiconductor that creates deficiencies of valence electrons. “n-type” refers to the addition of impurities that contributes free electrons to an intrinsic semiconductor. When the semiconductor material is doped with a p-type dopant, the resulting S/D regions 164 are referred to herein as being p-doped and when the semiconductor material is doped with a n-type dopant, the resulting S/D regions 164 are referred to herein as being n-doped.

The S/D regions 164 may be epitaxially grown or formed. In some examples, the S/D regions 164 are formed by in-situ doped epitaxial growth. The use of an in-situ doping process is merely an example. For instance, one may instead employ an ex-situ process to introduce dopants into the S/D regions 164. Other doping techniques can be used to incorporate dopants in the S/D regions 164.

In some examples, the epitaxial growth that forms the S/D region 164 occurs or is promoted from the upper surface of etch stop layer 152, from the exposed sidewalls of the active nanolayers 108, or the like, while epitaxial growth may be limited or does not occur from neighboring STI regions.

The ILD 176 may be formed by depositing a blanket dielectric material over the S/D region(s) 164, over the STI regions, over the sacrificial gate structures 130, over the gate spacers 142, and the like. The ILD 176 can be composed any suitable dielectric material, such as, for example, porous silicates, carbon doped oxides, silicon dioxides, silicon nitrides, silicon oxynitrides, or other dielectric materials. A planarization process, such as a CMP, may be performed to remove excess ILD 176 material and to remove the sacrificial gate caps 134 of the sacrificial gate structures 130, thereby exposing the sacrificial gate 132 thereunder.

FIG. 9 depicts cross-sectional views of the semiconductor IC device 100 after fabrication operations, in accordance with embodiments of the present disclosure. In the depicted fabrication stages, the sacrificial gate structures 130 may be removed and a respective replacement gate structure 170 may be formed in place thereof.

The sacrificial gate structures 130 may be removed by initially removing the sacrificial gate 132 and sacrificial gate oxide by a removal technique, such as one or more series of etches. For example, such removal may be accomplished by a wet chemical etching process in which one or more chemical etchants are used to remove the sacrificial gate 132 and sacrificial gate oxide of the sacrificial gate structures 130 selective to the active nanolayers 108, inner spacers 146, gate spacers 142, STI regions, or the like.

Next, or simultaneously, the active nanolayers 108 may be released by removing the sacrificial nanolayers 106 within the nanolayer stacks. The sacrificial nanolayers 106 may be removed by a removal technique, such as one or more series of etches. After the removal of sacrificial nanolayers, void spaces may be formed above and/or below the active nanolayers 108.

The replacement gate structure 170 may be formed in place of the removed sacrificial gate structures 130 around the released active nanolayers 108, upon STI regions, upon the bottom isolation region 144, etc. The replacement gate structure(s) 170 may be formed by forming an interfacial layer on the gate spacers 142, on the active nanolayers 108, on the substrate structure 102, on the inner spacers 146, etc. that are interior to and/or upon the respective surfaces interior to the opening created by the removal of the sacrificial gate structure 130 and the releasing of the active nanolayers 108.

The replacement gate structure(s) 170 may be further formed by depositing a high-κ layer to cover the exposed surfaces of the interfacial layer. A high-κ material is a material with a higher dielectric constant than that of SiO₂. The high-κ layer can include a single layer or multiple layers, such as metal layer, liner layer, wetting layer, and adhesion layer. The replacement gate structure(s) 170 may be further formed by depositing a work function (WF) gate upon the high-κ layer. The WF gate can be comprised of a conductor or metal. In general, the WF gate sets the threshold voltage (Vt) of the device. The high-κ layer may separate the WF gate from the nanolayer channel (i.e., active nanolayer 108). Other metals that may be desired to further fine tune the effective work function (eWF) and/or to achieve a desired resistance value associated with current flow through the gate in the direction parallel to the plane of the active nanolayers 108.

The replacement gate structure(s) 170 may be further formed by depositing a conductive gate 172. In an example, when none of the previous replacement gate material(s) are utilized in the replacement gate structures, the conductive gate 172 may be formed upon the same or similar surfaces as those upon which the interfacial layer, described above, may be formed. In other examples, when one or more of the interfacial layer, the high-κ layer, the WF gate, or the like, are or are not utilized in the replacement gate structures 170, the conductive gate 172 may be formed upon the most recent structural formation thereof.

The conductive gate 172 can be comprised of a conductor material and/or metal, such as but not limited to, e.g., tungsten, aluminum, ruthenium, rhodium, cobalt, copper, tantalum, titanium, carbon nanowire materials including graphene, or the like. After the replacement gate structure 170 formation, the replacement gate structure 170 may be recessed, thereby forming a void between gate spacers 142 and a gate cap 174 may be formed within such void. The cate cap 174 may be formed by depositing a dielectric material, such as a silicon dioxide, silicon nitride, or a combination thereof upon semiconductor IC device 100. A planarization process, such as a CMP, may be performed to remove excess The gate cap 174 material and to expose the ILD 176. Therefore, respective top surfaces of the gate spacers 142, the gate cap 174, and ILD 176 may be substantially horizontal and/or substantially coplanar.

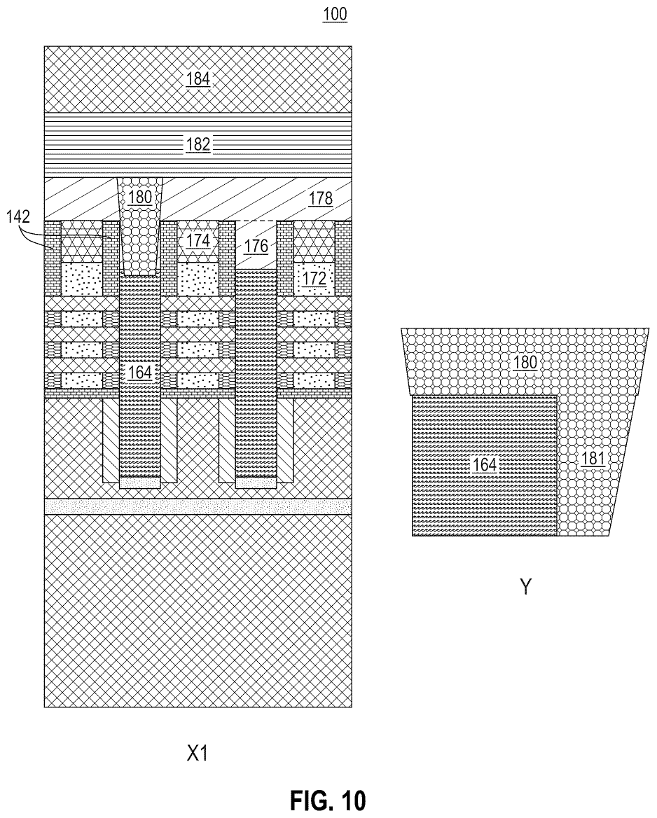

FIG. 10 depicts cross-sectional views of the semiconductor IC device 100 after fabrication operations, in accordance with embodiments of the present disclosure. In the depicted fabrication stages, a frontside contact ILD 178 may be formed, frontside contacts 180 and frontside vias 181 may be formed, a frontside back end of line (BEOL) network 182 may be formed, and a carrier wafer 184 may be bonded thereto.

The frontside contact ILD 178 may be formed upon respective top surfaces of replacement gate structure(s) 170, ILD 176, gate caps 174, and gate spacers 142. The frontside contact ILD 178 may be formed by depositing a dielectric material, such as, for example, porous silicates, carbon doped oxides, silicon dioxides, silicon nitrides, silicon oxynitrides, or other dielectric materials. The material of the frontside contact ILD 178 may be the same as the material of the ILD 176, as depicted. Alternatively, the frontside contact ILD 178 may be a relatively different dielectric material.

The frontside contacts 180 and frontside contact vias 181 may be formed by patterning respective frontside contact openings within the ILD 176 and the frontside contact ILD 178, respectively, from the frontside (i.e., from above the semiconductor IC device 100, as depicted, downward to respective structures thereof). The frontside contacts 180 and frontside contact vias 181 may be in direct or indirect physical and electrical contact with respective material(s) of one or more regions of the semiconductor IC device 100. For example, the frontside contact 180 may be directly connected to a frontside surface of an associated S/D region 164 and a frontside contact via 181 may be directly connected to a sidewall or side surface of the associated S/D region 164. For clarity, as depicted, the frontside contact vias 181 may be integral with (i.e., no interfacial resistance across the frontside contact 180 and frontside contact via 181) or in direct contact with the frontside contact 180. In another example, a frontside contact 180 may be directly connected to a replacement gate structure 170 (not shown in the X1 cross-section). For example, the frontside contact 180 may be directly connected to the conductive gate 172 of the replacement gate structure 170.

The frontside contact(s) 180 and frontside contact via 181 may be formed by depositing conductive material such as metal into the respective frontside contact opening(s). In an example, frontside contact(s) 180 and frontside contact via 181 may be formed by depositing a liner, such as Ni, NiPt or Ti, etc. into the contact opening(s), depositing an adhesion liner, such as TiN, TaN, etc. upon the liner, and by depositing a conductive fill, such as Al, Ru, W, Co, Cu, etc. upon the metal adhesion liner. Subsequently, a planarization process, such as a CMP process or a mechanical grinding process, may remove excess portions of the liner, the metal adhesion liner, and the conductive fill. In embodiments, the frontside contact(s) 180 and frontside contact via 181 are fabricated in middle-of-line (MOL) fabrication operations and may be illustrations of MOL frontside interconnect features.

The frontside BEOL network 182 may be formed over the frontside contact ILD 178 and upon the frontside contacts 180. Respective wires within the frontside BEOL network 182 may be electrically connected to the one or more S/D regions 164, to the one or more replacement gate structure(s) 170, or the like, by a respective frontside contact(s) 180. For example, respective wire(s) within the frontside BEOL network 182 may be electrically connected to appropriate S/D regions 164 by a frontside contact 180, another and different group of respective wire(s) within the frontside BEOL network 182 may be electrically connected to appropriate replacement gate structures 170, etc. by a different frontside contact 180.

The frontside BEOL network 182 can include one or more interconnect dielectric material layers (including one of the dielectric materials mentioned above for the frontside ILD 176) and contains conductive wires (the conductive wires can be composed of any electrically conductive material, metal, electrically conductive metal alloy, or the like) embedded therein. In some embodiments, the frontside conductive wires within the frontside BEOL network 182 are composed of Cu. The frontside BEOL network 182 can include “x” numbers of frontside metal levels, wherein “x” is an integer starting from 1. The frontside BEOL network 182 may further contain conductive pads that are connected to one or more of the conductive wires and may be used to connect the semiconductor IC device 100 to an external and/or higher-level structure, such as a chip carrier, motherboard, or the like.

In the semiconductor IC device fabrication industry, there are three sections referred to in a build: front-end-of-line (FEOL), BEOL, and the section that connects those two together, the MOL. The FEOL is made up of devices, e.g., transistors, the BEOL is made up of interconnects and wiring, and the MOL includes interconnects between the FEOL and BEOL and material to prevent the diffusion of BEOL conductive material(s) to the FEOL devices.

The BEOL section is the portion of IC fabrication where the individual devices (e.g., transistors, capacitors, resistors, etc.) become interconnected with wiring on the semiconductor IC device, e.g., the metallization layer or layers of a wafer. The BEOL section includes contacts, insulating layers (dielectrics), metal levels, and bonding sites for chip-to-package connections. In the BEOL section, part of the fabrication stage contacts (pads), interconnect wires, vias and dielectric structures are formed. For modern IC processes, more than one metal layers may be added in the BEOL section.

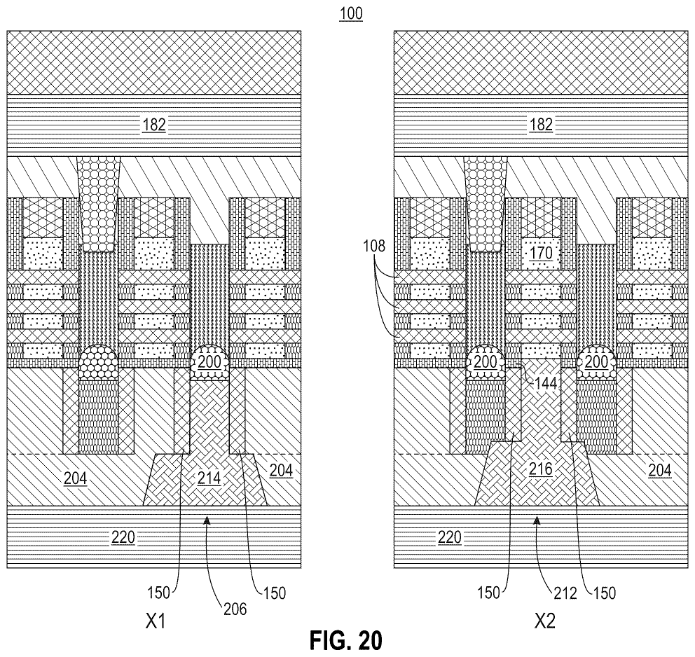

In the present example, there are multiple BEOL levels each on opposites sides of the semiconductor IC device 100. First, the frontside BEOL network 182 may be formed on the frontside of the semiconductor device 100. Subsequently, a backside BEOL network 220, as depicted in FIG. 20, may be formed.

The illustrated semiconductor IC device 100 may be further fabricated by bonding carrier wafer 184 to the frontside BEOL network 182. The carrier wafer 184 can include one of the semiconductor materials mentioned above for the semiconductor structure and the carrier wafer 184 may be attached to the semiconductor IC device 100 by a wafer-to-wafer bonding technique.

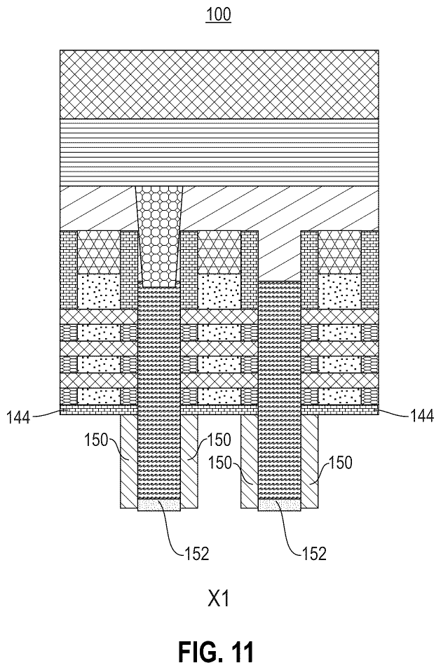

FIG. 11 depicts cross-sectional views of the semiconductor IC device 100 after fabrication operations, in accordance with embodiments of the present disclosure. In the depicted fabrication stages, the substrate structure 102 may be removed.

The substrate structure 102 may be recessed by flipping the semiconductor IC device 100 (not shown) and removing the substrate structure 102 by an appropriate substrative removal technique, such as a series of etches. For example, a first etch may remove the lower substrate 101 and may utilized the etch stop layer 103 as an etch stop, a next etch may remove the etch stop layer 103 and may utilize the upper substrate 104 as an etch stop. Finally, a third etch may remove the upper substrate. The etch that removes the upper substrate 104 may be timed or otherwise controlled to remove the material of the upper substrate 104 selective to the STI regions, to the etch stop layers 152, to the backside contact spacer(s) 150, to the to the bottom isolation regions 144, or the like.

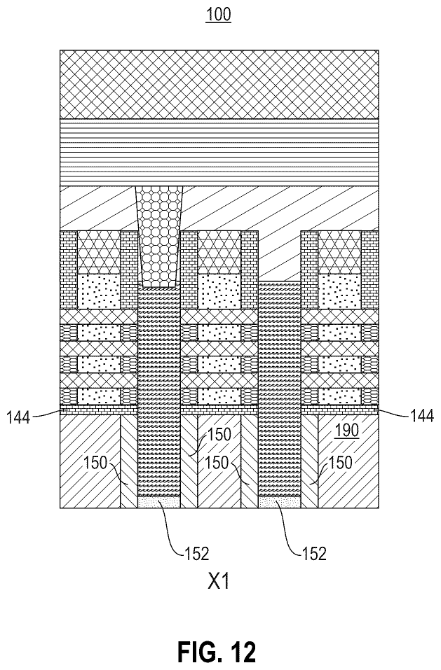

FIG. 12 depicts cross-sectional views of the semiconductor IC device 100 after fabrication operations, in accordance with embodiments of the present disclosure. In the depicted fabrication stages, a backside ILD 190 may be formed.

The backside ILD 190 may be formed upon the backside of the semiconductor IC device 100. The backside ILD 190 may be formed by depositing a dielectric material, such as, for example, porous silicates, carbon doped oxides, silicon dioxides, silicon nitrides, silicon oxynitrides, or other dielectric material(s) upon the STI regions, the etch stop layers 152, the backside contact spacer(s) 150, the to the bottom isolation regions 144, etc. Any appropriate deposition technique for forming the backside ILD 190 can be utilized. The backside ILD 190 can be formed using, for example, CVD, PECVD, ALD, flowable CVD, spin-on dielectrics, or PVD.

In an example, as depicted, the material of the backside ILD 190 may be the same material as the frontside ILD 176. In alternative examples, the material of the backside ILD 190 may be chosen to achieve a predetermined electrical isolation metric that the dielectric material of frontside ILD 176 could not achieve, if utilized. For example, frontside ILD 176 may be silicon dioxide and the backside ILD 190 may be a low-κ dielectric material. Subsequently, a planarization process, such as a CMP, may be performed to remove excess backside ILD 190 material and to expose the etch stop layers 152. As a result, the respective bottom surfaces of backside contact spacer(s) 150, etch stop layers 152, and backside ILD 190 may be substantially horizontal and/or substantially coplanar.

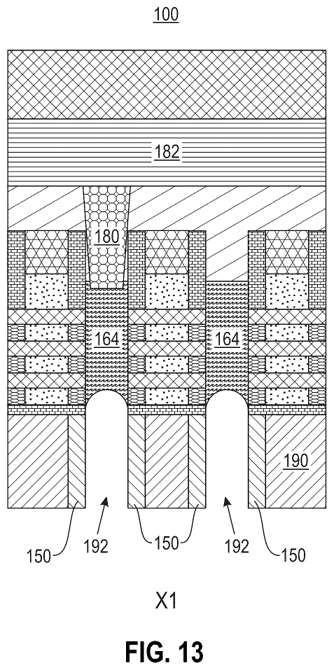

FIG. 13 depicts cross-sectional views of the semiconductor IC device 100 after fabrication operations, in accordance with embodiments of the present disclosure. In the depicted fabrication stages, backside contact openings 192 may be formed.

The backside contact openings 192 may be formed by lithography and etch process(es). In such process(es), a mask (not shown) may be applied to the backside of the semiconductor IC device 100 and patterned. Openings in the patterned mask may sequentially expose the portion(s) of the underlying etch stop layer 152 and S/D region 164 that are to be removed while other portions of semiconductor IC device 100 may be protected and retained. The backside contact opening 192 may be located in line with an associated S/D region 164 in which a frontside contact 180 is not connected. A backside contact opening 192 may be formed to remove expose the etch stop layer 152 there above and further formed to partially remove the respective S/D region 164 associated with the etch stop layer 152. In other words, the backside contact opening 192 may gouge the associated S/D region 164. For example, a lower portion of the S/D region 164 is removed while an upper portion of the exposed S/D region(s) 164 is retained. A well surface of the gouge within the S/D region(s) 164 may be below the bottommost active semiconductor nanolayer 108. The gouging or partial remove of the S/D region 164 may expose the backside contact spacer(s) 150 that were previously associated therewith.

For clarity, the backside contact opening 192 that is associated with a S/D region 164 that is connected to the frontside BEOL network 182 by the frontside contact 180 may further expose the associated frontside contact via 181 that is associated with that S/D region 164, as depicted in FIG. 10.

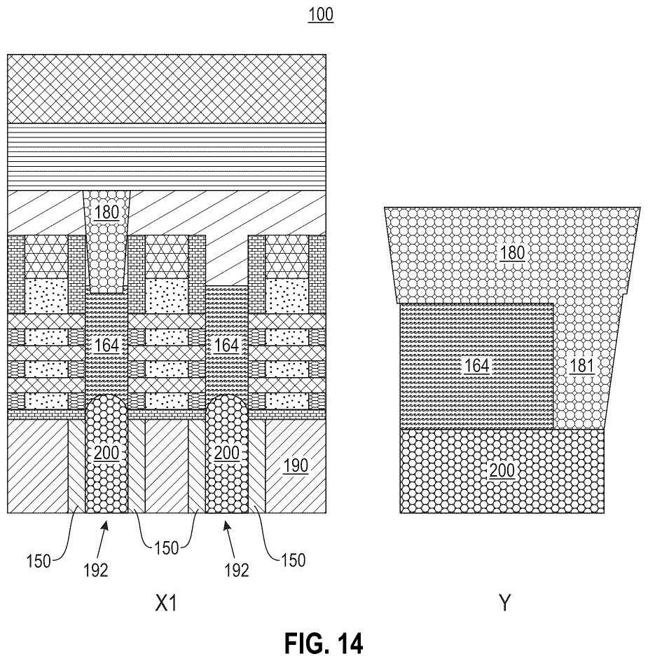

FIG. 14 depicts cross-sectional views of the semiconductor IC device 100 after fabrication operations, in accordance with embodiments of the present disclosure. In the depicted fabrication stages, a backside contact 200 may be formed within a respective backside contact opening 192.

A respective backside contact 200 may be formed within a respective backside contact opening 192 against the associated S/D region 164 (and against a frontside contact via 181, as appropriate) by depositing conductive material, such as metal, therein. In an example, multiple backside contacts 200 may be simultaneously formed by depositing a liner, such as Ni, NiPt or Ti, etc. onto the backside of semiconductor IC device 100 and into the backside contact openings 192, depositing an adhesion liner, such as TiN, TaN, etc. upon the liner, and by depositing a conductive fill, such as Al, Ru, W, Co, Cu, etc. upon the adhesion liner.

Subsequently, a planarization process, such as a CMP, may expose a bottom surface of the backside ILD 190. As a result, the respective bottom surfaces of backside contacts 200, backside contact spacer(s) 150, and backside ILD 190 may be substantially horizontal and/or substantially coplanar.

For clarity, the S/D region 164 that is connected to the frontside BEOL network 182 may be in direct contact with a wraparound contact that is effectively formed by the frontside contact 180, the frontside contact via 181, and the backside contact 200 that is associated therewith.

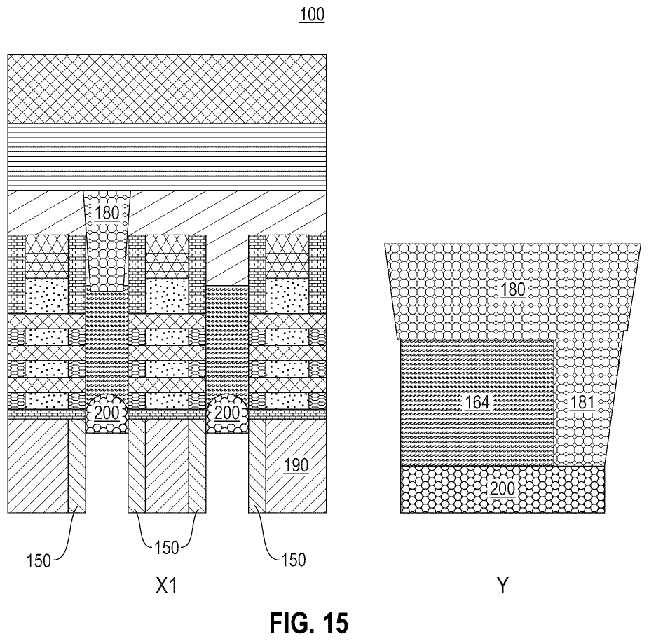

FIG. 15 depicts cross-sectional views of the semiconductor IC device 100 after fabrication operations, in accordance with embodiments of the present disclosure. In the depicted fabrication stages, the backside contacts 200 may be partially recessed.

The backside contacts 200 may be partially recessed by lithography and etch process(es). In such process(es), a mask (not shown) may be applied to the backside of the semiconductor IC device 100 and patterned. Openings in the patterned mask may sequentially expose the backside contacts 200 that are to be recessed while other portions of semiconductor IC device 100 may be protected and retained. The openings in the mask may be located in line with a particular backside contact 200. Using the mask to protect the underlying semiconductor IC device 100, the backside contacts 200 may be recessed. The etch may be directional and the associated backside contact spacer(s) 150 that are protected by the mask may be retained.

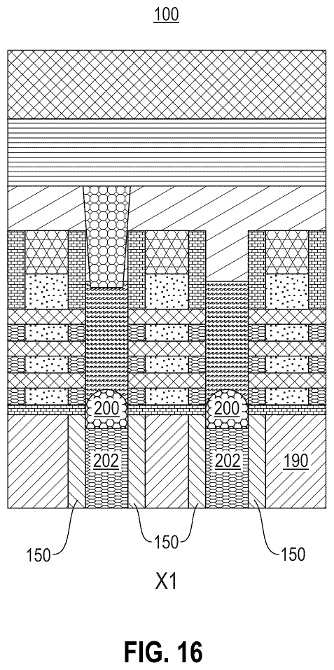

FIG. 16 depicts cross-sectional views of the semiconductor IC device 100 after fabrication operations, in accordance with embodiments of the present disclosure. In the depicted fabrication stages, a backside contact cap 202 may be formed upon a respective backside contact 200.

The backside contact cap 202 may be formed by depositing a dielectric material, such as a silicon dioxide, silicon nitride, or a combination thereof upon the backside of the semiconductor IC device 100. For example, the dielectric material may be deposited upon the respective backsides of the backside ILD 190, the backside contact spacer(s) 150, and the backside contacts 200. A planarization process, such as a CMP, may be performed to remove excess backside contact cap 202 material and to expose the backside ILD 190. Therefore, respective bottom or backside surfaces of the backside ILD 190, the backside contact caps 202, and backside contact spacer(s) 150 may be substantially horizontal and/or substantially coplanar.

In particular embodiment, the dielectric materials of the backside contact spacer(s) 150, the backside ILD 190, and the backside contact caps 202 may be relatively different. For example, the backside contact spacer(s) 150, the backside ILD 190, and the backside contact caps 202 may be formed of different dielectric materials so as to provide for etch selectively therebetween.

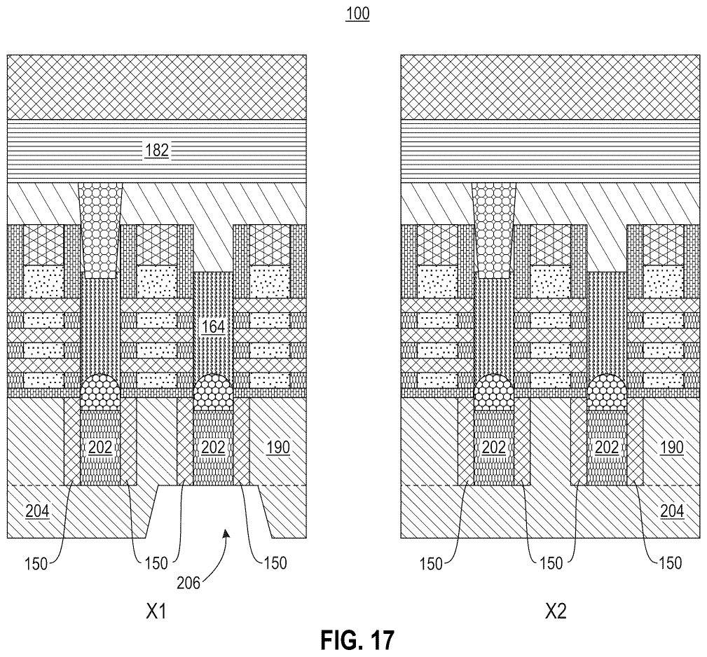

FIG. 17 depicts cross-sectional views of the semiconductor IC device 100 after fabrication operations, in accordance with embodiments of the present disclosure. In the depicted fabrication stages, a backside via ILD 204 may be formed and a backside via opening 206 may be formed.

The backside via ILD 204 may be formed upon the backside of the semiconductor IC device 100. The backside via ILD 204 may be formed by depositing a dielectric material, such as, for example, porous silicates, carbon doped oxides, silicon dioxides, silicon nitrides, silicon oxynitrides, or other dielectric material(s) upon the bottom or backside surfaces of the backside ILD 190, the backside contact caps 202, and backside contact spacer(s) 150. Any appropriate deposition technique for forming the backside via ILD 204 can be utilized. The backside via ILD 204 can be formed using, for example, CVD, PECVD, ALD, flowable CVD, spin-on dielectrics, or PVD.

In an example, as depicted, the material of the backside via ILD 204 may be the same material as the backside ILD 190. In alternative examples, the material of the backside via ILD 204 may be chosen to achieve a predetermined electrical isolation metric that the dielectric material of backside ILD 190 could not achieve, if utilized. For example, backside ILD 190 may be silicon dioxide and the backside via ILD 204 may be a low-κ dielectric material.

The backside via openings 206 may be formed by lithography and etch process(es). In such process(es), a mask (not shown) may be applied to the backside of the semiconductor IC device 100 and patterned. Openings in the patterned mask may be located in line with the underlying backside contact caps 202 and backside contact spacer(s) 150 that are to be removed while other portions of semiconductor IC device 100 may be protected and retained. The mask may protect the other portions of the semiconductor IC deice 100 and allow for an etchant to remove the unprotect portion of the backside via ILD 204 to be removed by a etch selective to one or more of the relatively materials of the backside contact caps 202 and backside contact spacer(s) 150. The backside via openings 206 may be formed to expose the associated backside contact caps 202 and backside contact spacer(s) 150. In particular embodiments, backside via openings 206 are formed in line with a S/D region 164 that is not connected to the frontside BEOL network 182 by a frontside contact. Subsequently, the mask may be removed.

For clarity, as depicted, the backside via opening 206 may be formed over only a portion of the associated backside contact cap 202. As such, a portion of the backside contact cap may be exposed by the backside via opening 206, as depicted in the X1 cross section, and another portion of the backside contact cap may be protected, as depicted in the X2 cross section.

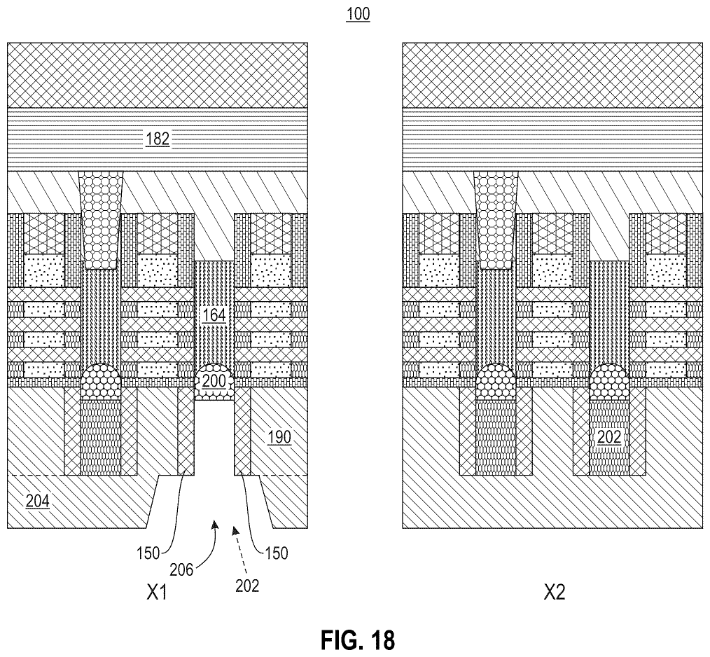

FIG. 18 depicts cross-sectional views of the semiconductor IC device 100 after fabrication operations, in accordance with embodiments of the present disclosure. In the depicted fabrication stages, the backside via opening 206 may be further processed by removing the exposed portion of the backside contact cap 202.

The removal of the exposed portion of the backside contact cap 202 may occur by a sequential self-aligned and/or directional etch process that removes the material of the backside contact cap 202 selective to the material(s) of the backside via ILD 204/backside ILD 190 and selective to the material of the backside contact spacer(s) 150. The portion of the backside contact cap 202 exposed by the backside via opening 206 may then be effectively or adequately removed, as depicted in the X1 cross section, while a remaining portion of the backside contact cap 202 that is not exposed by the backside via opening 206 is retained, as depicted in the X2 cross section. As such, there are surface(s) of the backside contact cap 202 that are exposed by the backside via opening 206 that are effectively created by the removal of one portion and retention of the other portion of the backside contact cap 202. The removal of the portion of the backside contact cap 202 effectively or adequately exposes at least a portion of the associated backside contact 200.

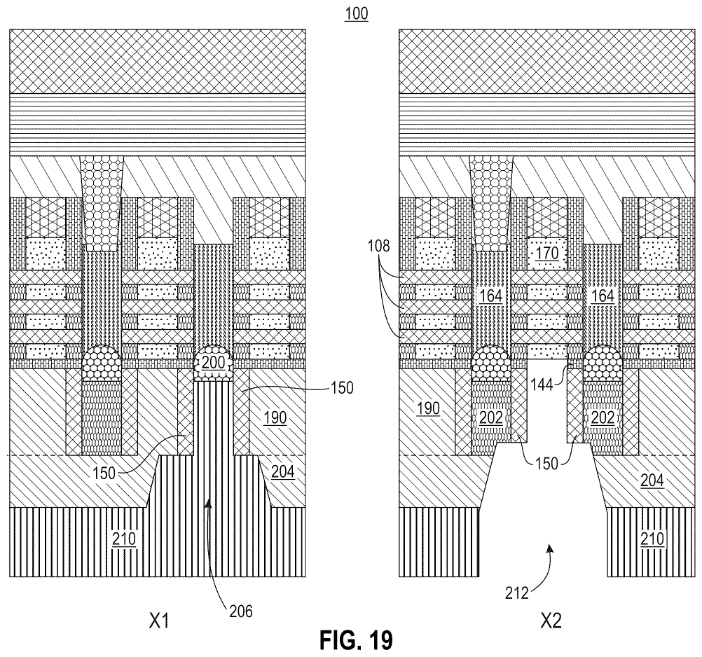

FIG. 19 depicts cross-sectional views of the semiconductor IC device 100 after fabrication operations, in accordance with embodiments of the present disclosure. In the depicted fabrication stages, a backside via opening 212 may be formed.

The backside via openings 212 may be formed by lithography and etch process(es). In such process(es), a mask 210 may be applied to the backside of the semiconductor IC device 100 and patterned to form backside via openings 212. The backside via openings 212 may be located in line substantially central between adjacent backside contact caps 202 or adjacent S/D regions 164 that are connected by the same active nanolayers 108. The mask 210 may protect the other portions of the semiconductor IC deice 100, such as the backside contact 200 and backside contact spacer(s) 150 associated with backside via opening 212. The mask 210 may further allow for an etchant to remove the unprotect portions of the backside via ILD 204 and backside ILD 190 by a etch selective to one or more of the relative materials of the backside contact caps 202 and backside contact spacer(s) 150. The backside via openings 212 may be formed to expose a bottom or backside of an associated replacement gate structure 170 between backside contact spacers 150. In particular embodiments, backside via openings 212 may gouge or partially etch backside contact caps 202 so as to punch through the bottom isolation region 144 and expose the associated replacement gate structure 170. Subsequently, the mask 210 may be removed.

FIG. 20 depicts cross-sectional views of the semiconductor IC device 100 after fabrication operations, in accordance with embodiments of the present disclosure. In the depicted fabrication stages, a backside S/D region contact via 214, a backside gate contact via 216, and a backside BEOL network 220 may be formed.

A respective backside S/D region contact via 214 and a respective backside gate contact via 216 may be formed within the backside via opening 206 or the backside via openings 212, respectively. In a particular fabrication scheme, a conductive material, such as metal, is deposited upon the backside via ILD 204 and within the backside via opening 206 and the backside via openings 212 against the associated backside contact 200 and/or the associated replacement gate structure 170. In an example, multiple backside S/D region contact via 214 and backside gate contact via 216 may be simultaneously formed by depositing a liner, such as Ni, NiPt or Ti, etc. onto the backside of semiconductor IC device 100 and into the backside via opening 206 and the backside via openings 212, depositing an adhesion liner, such as TiN, TaN, etc. upon the liner, and by depositing a conductive fill, such as Al, Ru, W, Co, Cu, etc. upon the adhesion liner.

Subsequently, a planarization process, such as a CMP, may expose a bottom surface of the backside via ILD 204. As a result, the respective bottom surfaces of the S/D region contact via 214, backside gate contact via 216, and backside via ILD 204 may be substantially horizontal and/or substantially coplanar.

For clarity, the S/D region contact via 214 may directly contact the backside contact 200 that is at least partially exposed by the backside via opening 206 and may directly contact adjacent backside contact spacers 150 that are connected to the same backside contact 200 as that S/D region contact via 214. Similarly, the backside gate contact via 216 may directly contact the backside of the replacement gate structure 170 that is at least partially exposed by the backside via opening 212 and may directly contact adjacent backside contact spacers 150 that are connected to adjacent and different backside contacts 200. The backside gate contact via 216 may further be connected to respective sidewalls of the bottom isolation region 144 that were formed by the backside via opening 212.

The backside BEOL network 220, such as a backside power distribution network (BSPDN) may be formed upon the S/D region contact via 214, the backside gate contact via 216, upon the backside via ILD 204. The backside BEOL network 220 may include signal wires for signal routing and power wires for providing power potential (e.g., VDD, VSS, etc.). The backside BEOL network 220 may allow for the distribution of power wires and signal wires between both the frontside and backside of the semiconductor IC device. The backside BEOL network 220 may further allow for the full or partial decoupling of signal routing and/or power routing and/or allows for dividing or splitting power wires and/or signal wires between both the frontside and backside of the semiconductor IC device. By incorporating the backside BEOL network 220, wire and contact routing congestion may be reduced, which may lead to further semiconductor IC device 100 scaling. For example, semiconductor IC devices that incorporate a backside BEOL network can result in a 30% area reduction and improved current-resistance (IR) drop compared to typical semiconductor IC devices that include solely a frontside BEOL network.

The backside BEOL network 220 may be electrically connected to one or more S/D regions 164 by way of a particular S/D region contact via 214 and associated backside contact 200. For example, a first wire within the backside BEOL network 220 may be electrically connected the S/D region contact via 214 and to the S/D region 164 through the associated backside contact 200. The backside BEOL network 220 may be electrically connected to one or more replacement gate structures 170 by way of a particular backside gate contact via 216. For example, a second wire within the backside BEOL network 220 may be electrically connected the replacement gate structure 170 through the associated backside gate contact via 216.

The backside BEOL network 220 can include one or more interconnect dielectric material layers and contains backside conductive wires and/or interconnects, such as VIAs, embedded therein. In some embodiments, the backside wires within the backside BEOL network 220 are composed of Cu. The backside BEOL network 220 can include “x” numbers of backside metal levels, wherein “x” is an integer starting from 1. If not included in frontside BEOL network 182, backside BEOL network 220 may further contain conductive pads that are connected to one or more of the backside metal wires and may be used to connect the semiconductor IC device 100 to the external and/or higher-level structure.

In an example, signal routing and power routing is effectively split between the frontside BEOL network 182 and the backside BEOL network 220. For example, at least 90% of the frontside metal wires (e.g., furthest from the depicted transistors) are signal routing metal wires and the remainder frontside metal wires which are usually present in metal levels closest to the transistors, can be used as power routing wires. Further in this example, at least 90% of the backside metal wires that are in metal levels closest to the backside contacts are power routing metal wires. Power routing wires may be less dense than signal routing wires. A signal routing wire is defined herein as a conductive feature, such as a wire, interconnect, or the like, that is configured to carry or have a functional or logical potential or signal that is to change or is otherwise dynamic over time. A power routing wire is defined herein as a conductive feature, such as a wire, trace, plane, or the like, that is configured to electrically carry power potential. For example, a power routing wire carries or otherwise has a functional power potential, such as VDD, VSS, or the like.

Semiconductor IC device 100 may be an integrated circuit (IC) chip. IC chips can be distributed by the fabricator in raw wafer form (that is, as a single wafer that has multiple unpackaged chips), as a bare die, or in a packaged form. In the latter case, the IC chip may mount in a single chip package (such as a plastic carrier, with leads that are affixed to a motherboard or other higher-level carrier) or in a multichip package (such as a ceramic carrier that has either or both surface interconnections or buried interconnections). In any case, the IC chip may be integrated with other chips, discrete circuit elements, and/or other signal processing devices as part of either (a) an intermediate product, such as a motherboard, or (b) an end product. The end product can be any product that includes the IC chip, ranging from toys and other low-end applications to advanced computer products having a display, a keyboard or other input device, and a central processor.

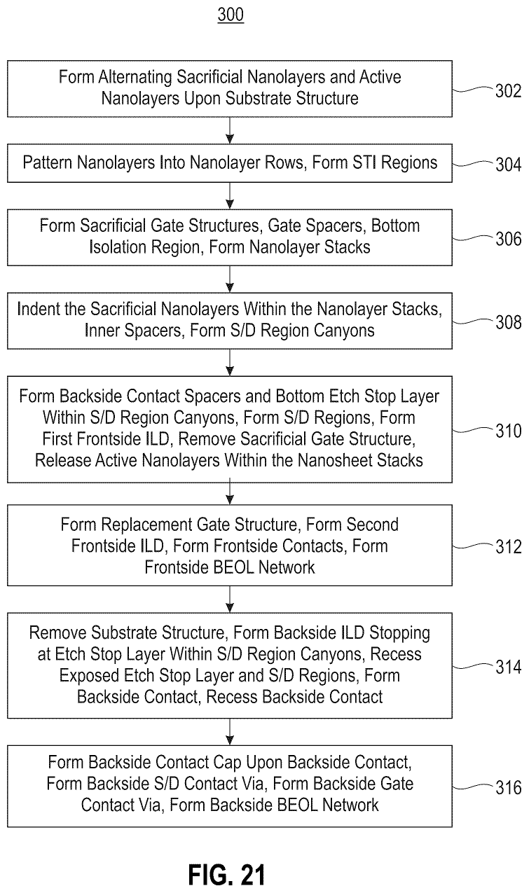

FIG. 21 depicts a flow diagram illustrating a method 300 to fabricate a semiconductor IC device, such as semiconductor IC device 100. The depicted fabrication operations of method 300 are illustratively depicted and described above with reference to one or more of FIG. 3 through FIG. 20 of the drawings, which describe the fabrication of semiconductor IC device 100, though the fabrication operations described in method 300 may be used to fabricate other types of semiconductor IC devices. The method 300 depicted herein is illustrative. There can be many variations to the diagram or operations described therein without departing from the spirit of the embodiments. For instance, the operations can be performed in a differing order, or operations can be added, deleted, or modified.

At block 302, method 300 may begin with forming nanolayers upon a substrate structure 102. For example, a bottommost sacrificial nanolayer is formed upon substrate structure 102 and series of alternating sacrificial nanolayers 106 and active nanolayers 108 (which may be referred to herein as channels) may be formed upon the bottommost sacrificial nanolayer.

At block 304, method 300 may continue with pattering the nanolayers into nanolayer rows 105 and with forming STI regions. At block 306, method 300 may continue with forming sacrificial gate structures 130, with forming gate spacers 142, bottom isolation regions 144, and forming nanolayer stacks 109.

At block 308, method 300 may continue with indenting the sacrificial nanolayers within the nanolayer stacks, with forming inner spacers 146, and with forming S/D region canyons 145. At block 310, method 300 may continue with forming backside contact spacers 150 and with forming etch stop layers 152 withing the S/D region canyons 145. Block 310 may further includes forming S/D region 164, forming ILD 176, with removing the sacrificial gate structures 130, and with releasing the active nanolayers 108 within the nanosheet stacks 109.

At block 312, method 300 may continue with forming replacement gate structures 170, with forming ILD 178, with forming frontside contacts 180, and with forming frontside BEOL network 182. At block 314, method 300 may continue with removing the substrate structure 102, with forming backside ILD 190 stopping at etch stop layer 152 within the S/D region canyons 145, with removing the etch stop layers 152, with gouging the associated S/D regions 164, with forming backside contacts 200, and with recessing the backside contacts 200.

At block 316, method 300 may continue with forming backside contact cap 202 upon the backside contact 200, with forming backside S/D region contact via 214, with forming backside gate region contact via 216, and with forming backside BEOL network 220.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor integrated circuit (IC) device comprising:
a backside contact in direct contact with a source/drain region;
a backside contact cap in direct contact with the backside contact;
a backside spacer in direct contact with respective sidewalls of the backside contact and the backside contact cap; and
a backside S/D region contact via in direct contact with the backside contact, in direct contact with the backside spacer, and in direct contact with the backside contact cap.

2. The semiconductor IC device of claim 1, further comprising:
a plurality of channels direct connected to a S/D region;
a gate directly connected to the plurality of channels; and
a backside gate contact via in direct contact with the gate, in direct contact with the backside spacer, and in direct contact with the backside contact cap.

3. The semiconductor IC device of claim 2, further comprising:
A backside interlayer dielectric (ILD) in direct contact with the backside spacer, in direct contact with the backside S/D region contact via, and in direct contact with the backside gate contact via.

4. The semiconductor IC device of claim 3, wherein the backside contact cap is composed of a first dielectric material, wherein the backside spacer is composed of a second dielectric material, wherein the backside ILD is composed of a third dielectric material, and wherein each of the first dielectric material, the second dielectric material, and the third dielectric material are relatively different dielectric materials.

5. The semiconductor IC device of claim 2, further comprising:
a gate spacer in direct contact with the gate; and
a plurality of inner spacers, each inner spacer of the plurality of inner spacers in direct contact with at least one channel of the plurality of channels.

6. The semiconductor IC device of claim 5, wherein the gate spacer, the plurality of inner spacers, and the backside spacer are vertically inline.

7. The semiconductor IC device of claim 2, wherein a topmost surface of the backside contact is below a bottommost channel of the plurality of channels and a top surface of the backside spacer.

8. A semiconductor integrated circuit (IC) device comprising:
a plurality of channels each directly connected to a first source/drain (S/D) region and directly connected to a second S/D region;
a first backside contact in direct contact with the first S/D region;
a second backside contact in direct contact with the second S/D region;
a first backside contact cap in direct contact with the first backside contact;
a second backside contact cap in direct contact with the second backside contact;
a first backside spacers in direct contact with respective sidewalls of the first backside contact and the first backside contact cap;
a second backside spacers in direct contact with respective sidewalls of the second backside contact and the second backside contact cap; and
a backside gate contact via in direct contact with a gate, in direct contact with one of the first backside spacers, and in direct contact with one of the second backside spacers.

9. The semiconductor IC device of claim 8, wherein the backside gate contact via is in direct contact with the first backside contact cap and in direct contact with the second backside contact cap.

10. The semiconductor IC device of claim 9, further comprising:
a frontside contact directly connected to a top surface of the second S/D region.

11. The semiconductor IC device of claim 10, further comprising:
a frontside contact via directly connected to the frontside contact, directly connected to the second backside contact, and directly connected to a sidewall of the second S/D region.

12. The semiconductor IC device of claim 11, further comprising:
a backside S/D contact via in direct contact with the first backside contact and in direct contact with the first backside spacers.

13. The semiconductor IC device of claim 12, further comprising:
a backside interlayer dielectric (ILD) in direct contact with the first backside spacers, in direct contact with the second backside spacers, in direct contact with the backside S/D contact via, and in direct contact with the backside gate contact via.

14. The semiconductor IC device of claim 8, further comprising:
a first plurality of inner spacers, each inner spacer of the first plurality of inner spacers in direct contact with at least one channel of the plurality of channels and in direct contact with the first S/D region; and
a second plurality of inner spacers, each inner spacer of the second plurality of inner spacers in direct contact with at least one channel of the plurality of channels and in direct contact with the second S/D region.

15. The semiconductor IC device of claim 14, wherein the first plurality of inner spacers and one of the first backside spacers are vertically inline and wherein the second plurality of inner spacers and one of the second backside spacers are vertically inline.

16. The semiconductor IC device of claim 8, wherein a respective topmost surface of the first backside contact and the second backside contact are both below a bottommost channel of the plurality of channels.

17. The semiconductor IC device of claim 12, wherein respective sidewalls of the first backside contact and respective sidewalls of the backside S/D contact via are directly connected to a respective one of the first backside spacers.

18. The semiconductor IC device of claim 12, wherein the backside gate contact via is in direct contact with a sidewall of one of the first backside spacers and in direct contact with a sidewall of one of the second backside spacers.

19. A semiconductor integrated circuit (IC) device comprising:
a first source/drain (S/D) region;
a second S/D region;
a first backside contact in direct contact with a backside of the first S/D region;
a second backside contact in direct contact with a backside of the second S/D region;
a first backside contact cap in direct contact with the first backside contact;
a second backside contact cap in direct contact with the second backside contact; and
a backside S/D contact via in direct contact with the first backside contact and in direct contact with the first backside contact cap.

20. The semiconductor IC device of claim 19, further comprising:
a backside gate contact via in direct contact with a gate, in direct contact with the first backside contact cap, and in direct contact with the second backside contact cap; and
a backside back end of line (BEOL) network connected to the backside S/D contact via and connected to the backside gate contact via.
